(19) United States
(12) Patent Application Publication
(10) Pub. No.: US 2016/0027796 A1
(43) Pub. Date: Jan. 28, 2016

(54) SEMICONDUCTOR DEVICES

(71) Applicants: Hyung-mo YANG, Hwaseong-si (KR); Sang-in KIM, Hwaseong-si (KR); Hae-na KIM, Daejeon-si (KR); Seung-min SON, Seongnam-si (KR); Hee-sung YANG, Seongnam-si (KR); Sang-min HAN, Gunpo-si (KR)

(72) Inventors: Hyung-mo YANG, Hwaseong-si (KR); Sang-in KIM, Hwaseong-si (KR); Hae-na KIM, Daejeon-si (KR); Seung-min SON, Seongnam-si (KR); Hee-sung YANG, Seongnam-si (KR); Sang-min HAN, Gunpo-si (KR)

(21) Appl. No.: 14/645,635

(22) Filed: Mar. 12, 2015

(30) Foreign Application Priority Data
Jul. 28, 2014 (KR) 10-2014-0096017

(51) Int. Cl. H01L 27/115; H01L 23/535

(52) U.S. Cl. CPC H01L 27/11582; H01L 23/535

(57) ABSTRACT

According to example embodiments, a semiconductor device includes a substrate, a plurality of word lines spaced apart from each other in a first direction on the substrate, a channel layer in a channel hole defined by the plurality of word lines, a gate insulating layer in the channel hole along an inner wall of the channel hole; and a self-aligned contact on an upper portion of the channel layer in the channel hole. The gate insulating layer is between the plurality of word lines and the channel layer. The first direction is perpendicular to an upper surface of the substrate. The channel hole exposes the upper surface of the substrate.

### CROSS-REFERENCE TO RELATED APPLICATION

This application claims priority under 35 U.S.C. §119 to Korean Patent Application No. 10-2014-0096017, filed on Jul. 28, 2014, in the Korean Intellectual Property Office, the disclosure of which is incorporated herein in its entirety by reference.

### BACKGROUND

The present application relates to a semiconductor device, and more particularly, to a semiconductor device having a vertical structure.

As the intensity of memory devices is increased, a memory device having a vertical transistor structure instead of a horizontal transistor structure has been suggested.

### SUMMARY

Example embodiments relate to a semiconductor device with a vertical structure.

Example embodiments also relate to a semiconductor device with excellent electrical characteristics.

According to example embodiments of inventive concepts, a semiconductor device includes: a substrate; a plurality of word lines spaced apart from each other in a first direction, is the first direction being perpendicular to an upper surface of the substrate the plurality of word lines defining a channel hole that exposes the upper surface of the substrate; a channel layer in the channel hole; a gate insulating layer in the channel hole along an inner wall of the channel hole, the gate insulating layer being between the plurality of word lines and the channel layer; and a self-aligned contact on an upper portion of the channel layer inside the channel hole. The self-aligned contact may include a width that increases from top to bottom.

In example embodiments, the self-aligned contact and a portion of the gate insulating layer may be formed to be at substantially the same level.

In example embodiments, a bottom surface of the self-aligned contact may contact at least a portion of an upper surface of the channel layer.

In example embodiments, an upper surface of the gate insulating layer may be above an uppermost surface of the plurality of word lines.

In example embodiments, a portion of the gate insulating layer may surround a lateral wall of the self-aligned contact.

In example embodiments, a contact spacer may be between the self-aligned contact and the gate insulating layer.

In example embodiments, the contact spacer may contact at least a portion of a lateral wall of the self-aligned contact.

In example embodiments, the contact spacer may surround a lateral wall of the self-aligned contact.

In example embodiments, the semiconductor device may further include an upper insulating layer on the plurality of word lines. The upper insulating later may further define the channel hole above a portion of the channel hole defined by the plurality of word lines. A portion of the gate insulating layer and the upper insulating layer may be at substantially the same level.

In example embodiments, an upper surface of the self-aligned contact and an upper surface of the upper insulating layer may be at substantially the same level.

According to example embodiments of inventive concepts, a semiconductor device includes: a substrate; a channel layer on the substrate, the channel layer extending in a first direction that is perpendicular to an upper surface of the substrate; a plurality of word lines arranged along a lateral wall of the channel layer, the plurality of word lines being spaced apart from each other in the first direction; a gate insulating layer between the channel layer and the plurality of word lines; a bit line contact on the channel layer; and a contact spacer surrounding a lateral wall of the bit line contact. The contact spacer may be positioned at substantially the same level as at least a portion of the gate insulating layer.

In example embodiments, the gate insulating layer may surround the channel layer and extend in the first direction, and an upper surface of the gate insulating layer and an upper surface of the contact spacer may be at substantially the same level.

In example embodiments, the at least a portion of the gate insulating layer may contact the contact spacer.

In example embodiments, an upper insulating layer surrounding the at least a portion of the gate insulating layer may be further formed, and the at least a portion of the gate insulating layer may be between the contact spacer and the upper insulating layer.

In example embodiments, an upper surface of the contact spacer and an upper surface of the bit line contact may be at substantially the same level.

According to example embodiments, a semiconductor device includes: a substrate, a memory cell on the substrate, a self-aligned contact, and a bit line connected to a top of the memory cell string through the self-aligned contact. The memory cell string includes a plurality of memory cell stacked on top of each other between a ground select transistor and a string select transistor. The self-aligned contact may include a width that increases from top to bottom.

In example embodiments, the memory cell string may include a channel layer, a plurality of electrodes spaced apart from each other in a vertical direction along a sidewall of the channel layer, and a gate insulating layer between the channel layer and the plurality of electrodes. The self-aligned contact may be on top of the channel layer. The self-aligned contact may be surrounded by the gate insulating layer.

In example embodiments, the bit line contact may contact an upper surface of the self-aligned contact and an upper surface of the gate insulating layer.

In example embodiments, the semiconductor device may further include a self-aligned contact spacer between the gate insulating layer and the self-aligned contact. A width of the self-aligned contact may decrease from top to bottom.

In example embodiments, a non-volatile memory device may include the above-described semiconductor device, a plurality of memory cell strings arranged in rows and columns on the substrate, a plurality of bit lines, a plurality of bit line contact, a plurality of word lines, and a core circuit. The plurality of bit lines may include the bit line. The plurality of memory cell strings may include the memory cell string. The plurality of bit line contacts may include the bit line contact. The core circuit may be connected to the rows and columns of the plurality of memory cell strings through the plurality of word lines and the plurality of bit lines, respectively. Each one of the plurality of memory cell strings may be connected to a corresponding one of the bit lines through a corresponding one of the self-aligned contacts.

### BRIEF DESCRIPTION OF THE DRAWINGS

The foregoing and other features of inventive concepts will be apparent from the more particular description of non-limiting embodiments of inventive concepts, as illustrated in the accompanying drawings in which like reference characters refer to like parts throughout the different views. The drawings are not necessarily to scale, emphasis instead being placed upon illustrating principles of inventive concepts. In the drawings:

FIG. 1 shows an equivalent circuit of a semiconductor device according to example embodiments;

FIG. 2A is a cross-sectional view of a semiconductor device according to example embodiments, and FIG. 2B shows a magnified view of an area 2B of FIG. 2A;

FIG. 3A is a cross-sectional view of a semiconductor device according to example embodiments, and FIG. 3B shows a magnified view of an area 3B of FIG. 3A;

FIGS. 4A to 4O are cross-sectional views showing a fabricating method of a semiconductor device according to example embodiments; and

FIG. 5 is a schematic block diagram showing a nonvolatile memory device according to example embodiments.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference characters and/or numerals in the drawings denote like elements, and thus their description may be omitted. As used herein, the term “and/or” includes any and all combinations of one or more of the associated listed items. Expressions such as “at least one of”, when preceding a list of elements, modify the entire list of elements and do not modify the individual elements of the list.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

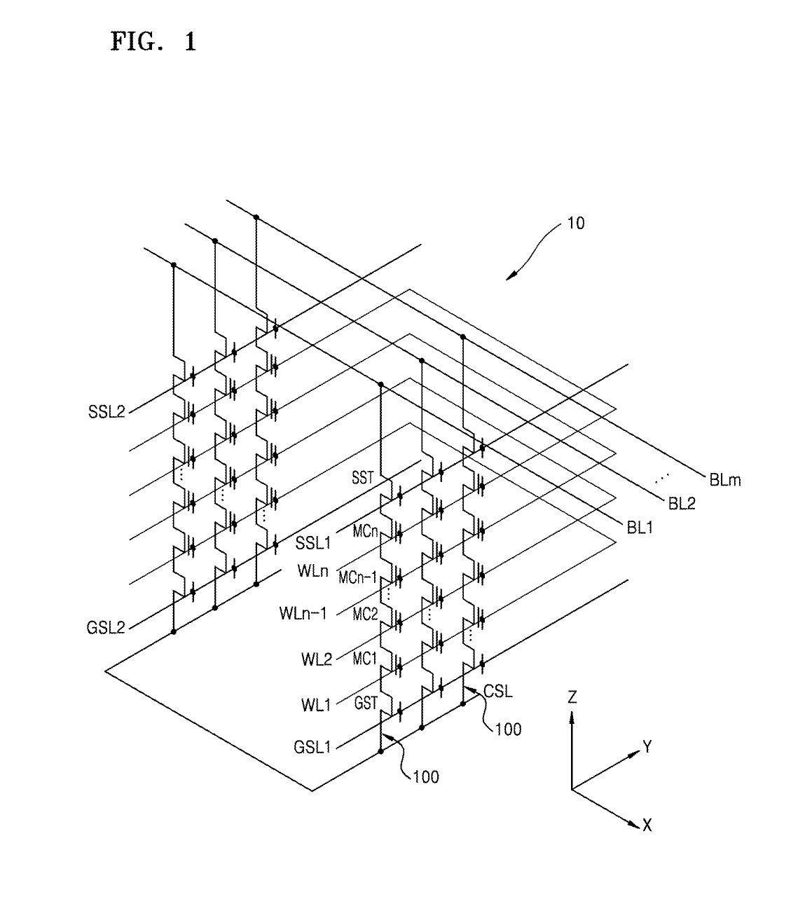

FIG. 1 shows an equivalent circuit of a semiconductor device according to example embodiments. In FIG. 1, the equivalent circuit of a NAND flash memory device having a vertical structure with a vertical channel structure is illustrated.

Referring to FIG. 1, a memory cell array 10 may include a plurality of memory cell strings 100. The memory cell array 10 includes a plurality of bit lines BL1, BL2, . . . , and BLm; a plurality of word lines WL1, WL2, . . . , WLn-1, and WLn; string selection lines SSL1 and SSL2; ground selection lines GSL1 and GSL2; and a common source line CSL. A plurality of memory cell strings 100 are formed between the bit lines BL1, BL2, . . . , and BLm and the common source line CSL. A memory cell block (not shown) is configured by the plurality of memory cell strings 100.

Each of the memory cell strings 100 includes a string selection transistor SST, a ground selection transistor GST and a plurality of memory cell transistors MC1, MC2, . . . , MCn-1, and MCn. A drain region of the string selection transistor SST is connected to the bit lines BL1, BL2, . . . , and BLm while a source region of the ground selection transistor GST is connected to the common source line CSL. The common source line CSL is a common region to which the source regions of the ground selection transistors GST are connected.

The string selection transistor SST may be connected to the string selection lines SSL1 and SSL2, and the ground selection transistor GST may be connected to the ground selection lines GSL1 and GSL2. Also, each of the memory cell transistors MC1, MC2, . . . , MCn-1, and MCn may be connected to the corresponding word lines WL1, WL2, . . . , WLn-1, and WLn, respectively.

The memory cell array 10 may be arranged in a three-dimensional (3D) manner. The memory cell transistors MC1, MC2, . . . , MCn-1, and MCn in the memory cell string 100 may be aligned serially in a Z-axis direction, which is perpendicular to the X-Y plane that is parallel to an upper surface of a substrate (not shown). In this regard, channel regions of the string and ground selection transistors SST and GST, and the memory cell transistors MC1, MC2, . . . , MCn-1, and MCn may be formed to be substantially perpendicular to the X-Y plane. Each X-Y plane may include m memory cells (where m is an integer equal to or greater than 1), and n X-Y planes (where n is an integer equal to or greater than 1) may be stacked in the Z-axis of the substrate. Therefore, m bit lines BL1, BL2, . . . , BLm-1, and BLm may be connected to each of the cell strings, and n word lines WL1, WL2, . . . , WLn-1, and WLn may be connected to the memory cell.

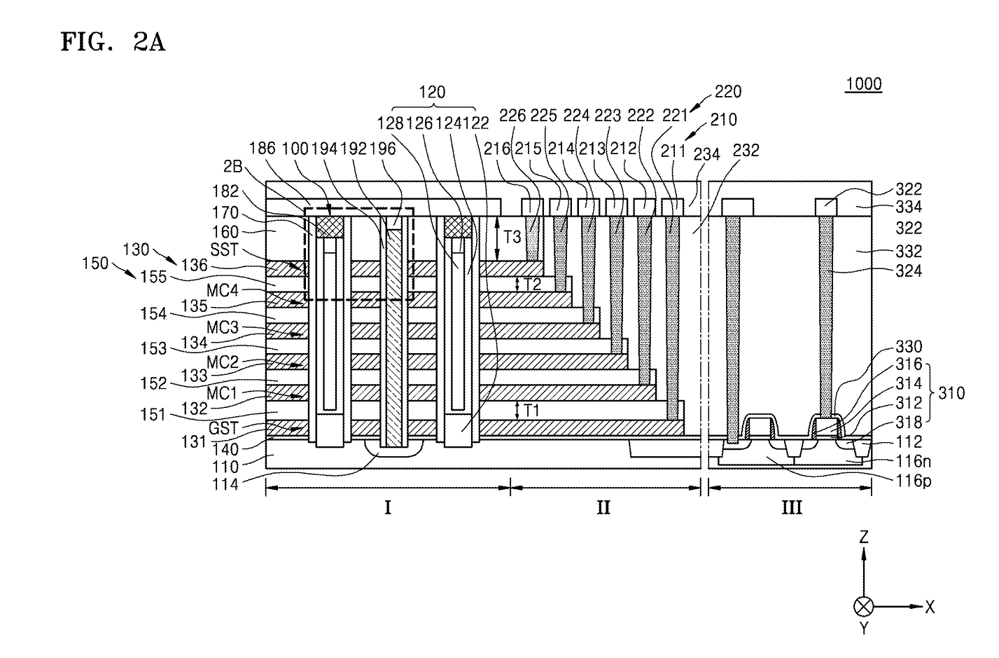

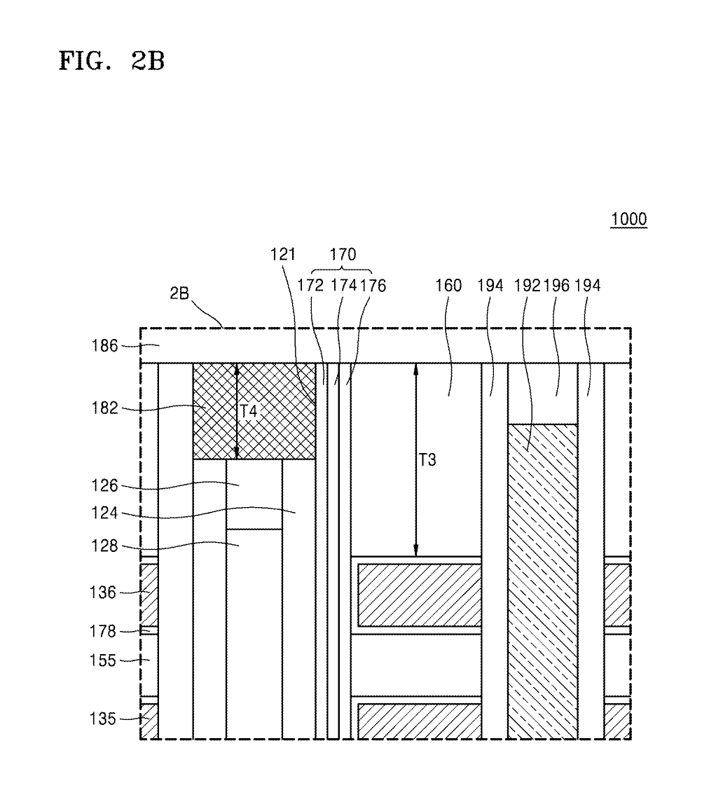

FIG. 2A is a cross-sectional view of a semiconductor device according to example embodiments, and FIG. 2B shows a magnified view of an area 2B of FIG. 2A.

Referring to FIG. 2A and FIG. 2B, a substrate 110 may have a main surface that extends in a X direction and in a Y direction. The substrate 110 may include a silicon substrate, a germanium substrate, a silicon-germanium substrate, a silicon-on-insulator (SOI) substrate, a germanium-on-insulator (GeOI) substrate, or the like. Although not illustrated, a p well (not shown) may further be formed on the substrate 110.

A cell region I, a connection region II, and a peripheral circuit region III may be defined on the substrate 110. The cell region I may be disposed on the substrate 110, the peripheral circuit region III may be disposed on at least one side of the cell region I, and the connection region II may be disposed between the cell region I and the peripheral circuit region III.

The plurality of memory cell strings 100 may be formed on the cell region I of the substrate 110. Each of the memory cell strings 100 may include a channel structure 120 that extends in a vertical direction on the substrate 110, and each of the memory cell strings 100 may include the ground selection transistor GST, a plurality of memory cell transistors MC1, MC2, MC3, and MC4, and the string selection transistor SST disposed along a lateral wall of the channel structure 120. Although not illustrated, a lower dummy transistor (not shown) may be selectively formed between the ground selection transistor GST and a lowermost memory cell transistor MC1, and an upper dummy transistor (not shown) may be further formed between an uppermost memory cell transistor MC4 and the string selection transistor SST in a selective manner.

An isolation region 112 may be formed at an edge portion of the connection region II of the substrate 110. The isolation region 112 may be a field region that defines an active region (not shown) of the memory cell string 100. In example embodiments, the isolation region 112 may be formed on the peripheral circuit region III of the substrate 110 to define an active region (not shown) of a peripheral circuit gate structure 310.

A common source region 114 may be disposed on an upper portion of the substrate 110 to extend in the Y direction. The common source region 114 may be an impurity region doped with a high concentration of n-type impurities. The common source region 114 may act as a source region that supplies a current to the memory cell string 100.

The channel structure 120 may be disposed to be spaced apart from the common source region 114 and to extend on the upper surface of the substrate 110 in the Z direction that is perpendicular to the X and Y direction. In example embodiments, a plurality of channel structures 120 may be disposed to be spaced apart from one another in the X direction, and in the Y direction, respectively. In example embodiments, a plurality of channel structures 120 may be disposed in a zig-zag manner in the Y direction. In other words, two channel structures 120Y disposed adjacent to each other in the Y direction may be disposed to be off-set in the X direction.

The channel structure 120 may include a first channel layer 122, a second channel layer 124, and a third channel layer 126.

A lower surface of the first channel layer 122 may directly contact the substrate 110 to be electrically connected to the substrate 110. The first channel layer 122 may act as a body contact (or a resistance reducing layer) so that the electrical resistance of the channel structure 120 is reduced, thereby increasing a cell current of the memory cell string 100 which flows through the channel structure 120 from the substrate 110. For example, the first channel layer 122 may include a silicon layer formed from the substrate 110 through a selective epitaxial growth (SEG) process, and the first channel layer 122 may include a p-type impurity such as aluminum (Al), boron (B), indium (In), or potassium (K). In example embodiments, an upper surface of the first channel layer 122 may be formed to be higher than the upper surface of the substrate 110. The first channel layer 122 may be formed to be higher than an upper surface of the ground selection transistor GST that is an upper surface of a first gate electrode 131.

The second channel layer 124 may be disposed to extend in the z direction on the upper portion of the first channel layer 122. In example embodiments, the second channel layer 124 may be formed in a cylinder shape having a closed bottom, or a cup shape. In example embodiments, the second channel layer 124 may include a polysilicon doped with n-type impurities such as phosphorous (P), arsenic (As), or antimony (Sb), or p-type impurities such as aluminum (Al), boron (B), indium (In), or potassium (K). In example embodiments, the second channel layer 124 may include an undoped polysilicon. The second channel layer 124 may act as a channel region for each of the memory cell transistors MC1, MC2, MC3, and MC4.

A buried insulating layer 128 may selectively be disposed to extend in the Z direction inside the channel structure 120. In particular, as illustrated in FIG. 2A, the buried insulating layer 128 may be formed along an inner wall of the second channel layer 124, formed in a cylinder shape with a closed bottom, to have a pillar shape extending in the Z direction. An upper surface of the buried insulating layer 128 may be positioned at a level lower than that of an upper surface of the second channel layer 124. However, in a case in which the buried insulating layer 128 is not formed, the second channel layer 124 having a pillar shape may be disposed on the upper portion of the first channel layer 122. In example embodiments, the buried insulating layer 128 may include silicon oxide.

The third channel layer 126 may be formed on a lateral wall of the second channel layer 124 and on the buried insulating layer 128. The third channel layer 126 may include a polysilicon doped with n-type impurities such as phosphorous (P), arsenic (As), or antimony (Sb).

First to sixth gate electrodes 131, 132, . . . , and 136 may be aligned to be spaced apart along the lateral wall of the channel structure 120 in the Z direction. In this case, for the sake of convenience, the first to sixth gate electrodes 131, 132, . . . , and 136 are collectively referred to as the gate electrodes 130. The gate electrodes 130 may be commonly connected to the adjacent memory cell strings 100 disposed in the Y direction. In example embodiments, the gate electrodes 130 may include tungsten, cobalt, nickel, tantalum, tungsten nitride, tungsten silicide, cobalt silicide, nickel silicide, tantalum silicide, or the like.

The first gate electrode 131 may correspond to the ground selection lines GSL1 and GSL2 (see FIG. 1). The second and fifth gate electrodes 132, 133, 134, and 135 may respectively correspond to the first to fourth word lines WL1, WL2, WLn-1, and WLn (see FIG. 1), and the sixth gate electrode 136 may correspond to the string selection lines SSL1 and SSL2 (see FIG. 1). Although four word lines are illustrated in FIG. 2A for the sake of convenience, the number of the word lines is not limited thereto and may vary according to the design of the memory cell string 100. Also, although the string selection lines SSL1 and SSL2 are illustrated to belong to one gate electrode 136 in FIG. 2A, the sixth gate electrodes 136 may be formed in two or more gate electrodes, and each of them may respectively be connected to first and second string lines (not shown).

In example embodiments, a lower insulating layer 140 may be disposed between the first gate electrode 131 and the substrate 110. The lower insulating layer 140 may include silicon oxide, silicon nitride, silicon oxynitride, and the like.

Insulating layers 151, 152, . . . , 155 (collectively 150) may be disposed between the adjacent gate electrodes 130. For example, a first insulating layer 151 may be formed between the first and second gate electrodes 131 and 132, and a second insulating layer 152 may be formed between the second and third gate electrodes 132 and 133. A fifth insulating layer 155 may be formed under a lower portion of an uppermost gate electrode 130, that is the sixth gate electrode 136. The thickness of each of the insulating layers 150 may vary depending on the distance between the adjacent gate electrodes 130. For example, the first insulating layer 151 formed between the first gate electrode 131 and the second gate electrode 132 has a large thickness, thereby securing a sufficient distance between the ground selection transistor GST and the first memory cell transistor MC1. For example, a first thickness T1 of the first insulating layer 151 in the vertical direction may be greater than a second thickness T2 of the fifth insulating layer 155 in the vertical direction.

An upper insulating layer 160 may be disposed on an upper portion of the uppermost gate electrode 130, that is, the sixth gate electrode 136. A third thickness T3 of the upper insulating layer 160 in the vertical direction may be greater than the thickness of each of the insulating layers 150 in the vertical direction. For example, the thickness T3 of the upper insulating layer 160 may be greater than the thickness T2 of the fifth insulating layer 155. Also, an upper surface of the upper insulating layer 160 may be positioned to be higher than an upper surface of the channel structure 120. The upper insulating layer 160 may include silicon oxide, silicon nitride, silicon oxynitride, or the like.

A gate insulating layer 170 may be disposed between the channel structure 120 and the gate electrodes 130. The gate insulating layer 170 may cover lateral walls of the first and second channel layers 122 and 124 and be disposed to extend in the Z direction. An upper surface of the gate insulating layer 170 and the upper surface of the upper insulating layer 160 may be at substantially the same level and may also be positioned to be higher than the upper surface of the channel structure 120.

The gate insulating layer 170 may include a tunnel insulating layer 172, a charge storage layer 174, and a blocking insulating layer 176 that are sequentially stacked on the lateral wall of the channel structure 120. The tunnel insulating layer 172 may tunnel charges to the charge storage layer 174 by using a Fowler-Nordheim (F-N) method. For example, the tunnel insulating layer 172 may include silicon oxide. The charge storage layer 174 may be a charge trapping layer that stores electrons tunneled via the tunnel layer. For example, the charge storage layer 174 may include silicon nitride, quantum dots, or nanocrystals. The blocking insulating layer 176 may include silicon oxide or a high-k dielectric material. Here, the high-k dielectric material refers to a dielectric material having a higher dielectric constant than that of silicon oxide.

In addition, a diffusion barrier layer 178 may further be formed between the gate electrodes 130 and the insulating layers 150, and between the gate electrodes 130 and the gate insulating layer 170. For example, the diffusion barrier layer 178 may include at least one selected from aluminum oxide (AlOx), tungsten nitride (WNx), tantalum nitride (TaNx), or titanium nitride (TiNx), or the like.

A self-aligned contact 182 may be formed on the upper portion of the channel structure 120 to be in contact with the gate insulating layer 170. A bottom surface of the self-aligned contact 182 may be directly in contact with the upper surface of the channel structure 120, and a lateral wall of the self-aligned contact 182 may be aligned with the lateral wall of the channel structure 120. An upper surface of the self-aligned contact 182 and the upper surface of the gate insulating layer 170 may be at substantially the same level, and a portion of the gate insulating layer 170 that is positioned at substantially the same level as the self-aligned contact 182 may be disposed to surround the lateral wall of the self-aligned contact 182.

In particular, when defining a channel hole 121 that penetrates through the lower insulating layer 140, the gate electrodes 130 and insulating layers 150 that are alternately stacked, and the upper insulating layer 160, on the substrate 110 in the Z direction, the gate insulating layer 170 is formed on a lateral wall of the channel hole 121, and the channel structure 120 is disposed to fill the channel hole 121 from a bottom portion thereof to a desired (and/or predetermined) height thereof. The self-aligned contact 182 may be disposed on the upper portion of the channel structure 120 within the channel hole 121 to fill the a portion of the channel hole 121, which were not filled with the channel structure 120. Accordingly, the lateral wall of the self-aligned contact 182 may be aligned with the lateral wall of the channel structure 120. In example embodiments, a fourth thickness T4 of the self-aligned contact 182 in the vertical direction may be less than the third thickness T3 of the upper insulating layer 160 in the vertical direction.

A bit line 186 may be disposed to extend in the X direction on the upper insulating layer 160 and the self-aligned contact 182. The bit line 186 may be formed to directly contact the self-aligned contact 182, and thus the self-aligned contact 182 may act as a bit line contact that connects the bit line 186 and the channel structure 120. The self-aligned contact 182 may be directly formed on the upper portion of the channel structure 120 inside the channel hole 121 via a self-aligning method using a portion of the gate insulating layer 170 as an aligning spacer, and thus the contact area between the self-aligned contact 182 and the channel structure 120 may be increased, thereby reducing an electric resistance between the channel structure 120 and the bit line 186.

A common source line 192 may be formed on the common source region 114 of the substrate 110. For example, the common source line 192 may be formed on a portion of the common source region 114 in the Y direction. In example embodiments, the common source line 192 may be formed on an entire upper portion of the common source region 114 in the Y direction.

A common source line spacer 194 including an insulating material may be formed on a lateral wall of the common source line 192. The common source line spacer 194 may be formed along a lateral wall of the gate electrodes 130 to act as an isolation layer that electrically insulates the gate electrodes 130 from the common source line 192.

A common source line insulating layer 196 may further be formed on an upper portion of the common source line 192. The common source line insulating layer 196 may be disposed between the common source line 192 extending in the Y direction, and the bit line 186 extending in the X direction on the upper portion of the common source line 192 to act as an isolation layer that electrically separates the common source line 192 from the bit line 186.

The first gate electrode 131, a portion of the first channel layer 122 adjacent thereto, and a portion of the gate insulating layer 170 may constitute the ground selection transistor GST. In addition, the second to fifth gate electrodes 132, 133, 134, and 135, portions of the second channel layer 124 adjacent thereto, and portions of the gate insulating layer 170 adjacent thereto may constitute the first to fourth memory cell transistors MC1, MC2, MC3, and MC4. Also, the sixth gate electrode 136, a portion of the second channel layer 124 adjacent thereto, and a portion of the gate insulating layer 170 may constitute the string selection transistor SST. Although four memory cell transistors are, for the sake of convenience, illustrated in FIG. 2A, the number of the memory cell transistors is not limited thereto and may vary depending on the design of the memory cell string 100.

The first to sixth gate electrodes 131, 132, 133, . . . , and 136 may extend to the connection region II of the substrate 110. The length of gate electrodes 130 extending to the connection region II in the X direction may be sequentially decreased from the first gate electrode 131 to the sixth gate electrode 136. In other words, the length of the second gate electrode 132 extending to the connection region II may be shorter than the first gate electrode 131 extending thereto by a desired (and/or predetermined) length, and thus a stepped portion may be formed between the first gate electrode 131 and the second gate electrode 132. In the same manner, a plurality of stepped portions between the first to sixth gate electrodes 131, 132, 133, . . . , and 136 may be formed on the connection region II.

A plurality of gate wiring lines 211, 212, 213, 214, 215, and 216 (collectively 210) may be disposed on the connection region II of the substrate 110. The first to sixth gate wiring lines 211, 212, 213, 214, 215, and 216 may be electrically connected to the first to sixth gate electrodes 131, 132, 133, 134, 135, and 136 (collectively 130) via the first to sixth contact plugs 221, 222, 223, 224, 225, and 226 (collectively 220). In other words, the first gate wiring line 211 may be a conductive line that transmits a signal from the peripheral gate structure 310 of the peripheral circuit region III to the ground selection lines GSL1 and GSL2 (see FIG. 1). The second to fifth gate wiring lines 212, 213, 214, and 215 may also be conductive lines that transmit a signal from the peripheral gate structure 310 of the peripheral circuit region III to the first to fourth word lines WL1, WL2, WLn-1, and WLn (see FIG. 1). The sixth gate wiring line 216 may be a conductive line that transmits a signal from the peripheral gate structure 310 of the peripheral circuit region III to the string selection lines SSL1 and SSL2 (see FIG. 1).

A first insulating interlayer 232 may be formed on the substrate 110 to cover the gate electrodes 130 and the insulating layers 150 extending toward an upper portion of the connection region II. The first insulating interlayer 232 may be formed to surround the first to sixth contact plugs 221, 222, 223, 224, 225, and 226, and the gate wiring lines 210 may be disposed to extend in the Y direction on the first insulating interlayer 232.

A second insulating interlayer 234 may be formed to cover the bit line 186 and the gate wiring lines 210 on the first insulating interlayer 232.

The peripheral gate structure 310 may be disposed on the peripheral circuit region III of the substrate 110. An active region (not shown) may be defined by the isolation region 112 on the peripheral circuit region III of the substrate 110, and a p well 116p and an n well 116n may be formed on the active region. An NMOS transistor may be formed on the p well 116p while a PMOS transistor may be formed on the n well 116n. The peripheral gate structure 310 may include a peripheral gate insulating layer 312, a peripheral gate electrode 314, a peripheral spacer 316, and a source/drain region 318. The peripheral gate structure 310 may form a transistor to drive the memory cell transistors MC1, MC2, MC3, and MC4 via the gate wiring lines 210 of the connection region II.

A peripheral wiring line 322 and a peripheral contact plug 324 may be formed on the peripheral circuit region III of the substrate 110 to be electrically connected to the peripheral gate structure 310. An etch stop layer 330 may cover a peripheral gate structure 300 on the substrate 110. The etch stop layer 330 may include an insulating material such as silicon nitride and silicon oxynitride, and may be formed to have a desired (and/or predetermined) thickness to conformally cover the peripheral gate structure 310. A third insulating interlayer 332 and a fourth insulating interlayer 334 may be sequentially formed on the etch stop layer 330. Although a peripheral wiring line 322 and a peripheral contact plug 324 are, for example, illustrated in FIG. 2A, a stacked structure of a plurality of wiring lines (not shown) may be formed depending on the type and characteristic of the peripheral gate structure 310.

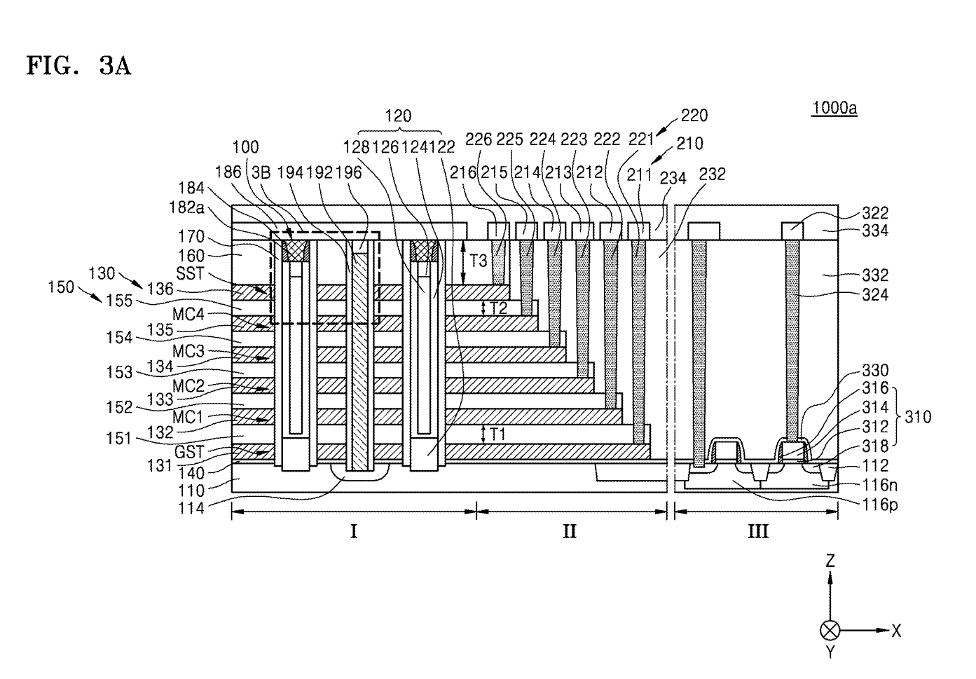

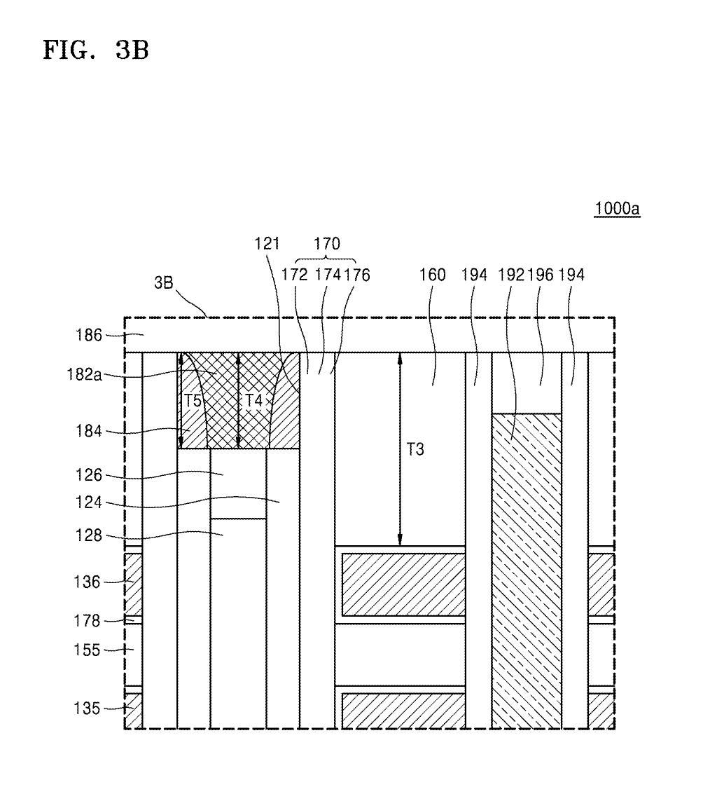

FIG. 3A is a cross-sectional view of a semiconductor device according to example embodiments, and FIG. 3B shows a magnified view of an area 3B of FIG. 3A. The semiconductor device 1000a in FIGS. 3A and 3B is similar to the semiconductor device 1000 in FIGS. 2A and 2B except that the semiconductor device 1000a further includes a self-aligned contact spacer 184, and thus only the difference between them will be explained here below. Also, like reference numerals in FIGS. 2A to 3B denote like elements.

Referring to FIGS. 3A and 3B, the self-aligned contact spacer 184 may be disposed to surround a self-aligned contact 182a on the upper portion of the channel structure 120. A bottom surface of the self-aligned contact spacer 184 may directly contact the channel structure 120, and a lateral wall of the self-aligned contact spacer 184 may partially contact a portion of the gate insulating layer 170. An upper surface of the self-aligned contact 182a and an upper surface of the self-aligned contact spacer 184 may be at substantially the same level.

In particular, when defining the channel hole 121 penetrating through the lower insulating layer 140, the gate electrodes 130 and the insulating layers 150 that are alternately stacked, and the upper insulating layer 160, on the substrate 110 and extending in the Z direction, the gate insulating layer 170 is formed along the lateral wall of the channel hole 121 while the channel structure 120 is disposed to fill the channel hole 121 from a bottom portion thereof to a desired (and/or predetermined) height. The self-aligned contact spacer 184 may be formed on the upper portion of the channel structure 120 inside the channel hole 121, and along the lateral wall of the channel hole 121 where the channel hole 121 is not filled with the channel structure 120 so that the self-aligned contact 182a may fill the unfilled portion of the channel hole 121. Accordingly, the lateral wall of the self-aligned contact spacer 184 may be aligned with the lateral wall of the channel structure 120.

In example embodiments, the self-aligned contact spacer 184 may be positioned at substantially the same level as the upper insulating layer 160. In example embodiments, a fifth thickness T5 of the self-aligned contact spacer 184 in the vertical direction may be substantially the same as the fourth thickness T4 of the self-aligned contact 182a in the vertical direction, and the fifth thickness T5 of the self-aligned contact spacer 184 in the vertical direction may be less than the third thickness T3 of the upper insulating layer 160 in the vertical direction. In example embodiments, the self-aligned contact spacer 184 may include silicon oxide, silicon nitride, silicon oxynitride, or the like.

The self-aligned contact 182a may be directly formed on the upper portion of the channel structure 120 inside the channel hole 121 via a self-aligning method using the self-aligned contact spacer 184 as an aligning spacer, and thus the contact area between the self-aligned contact 182a and the channel structure 120 is increased, thereby reducing an electric resistance between the channel structure 120 and the bit line 186.

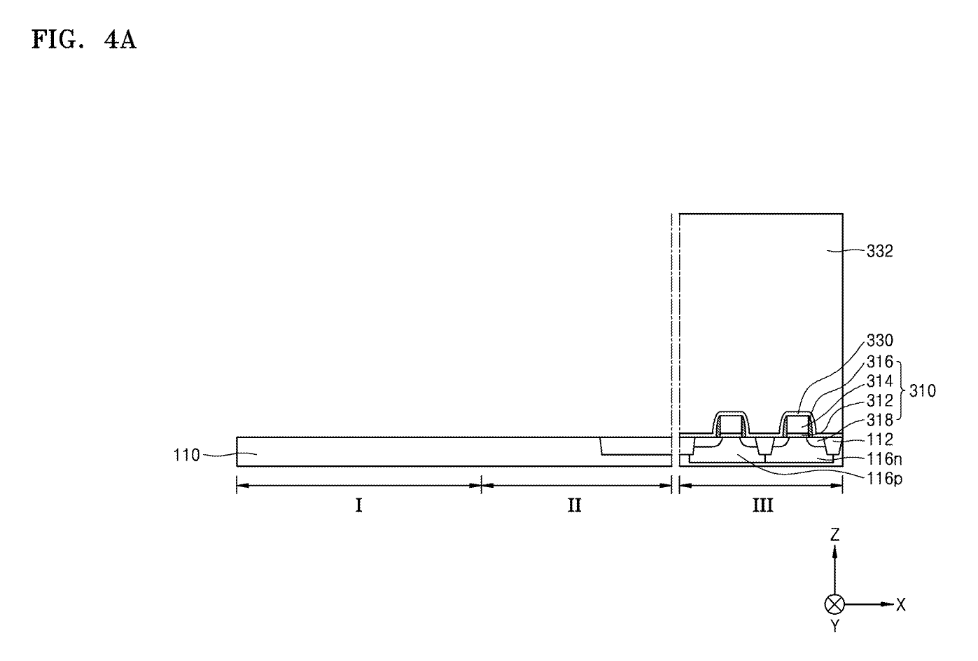

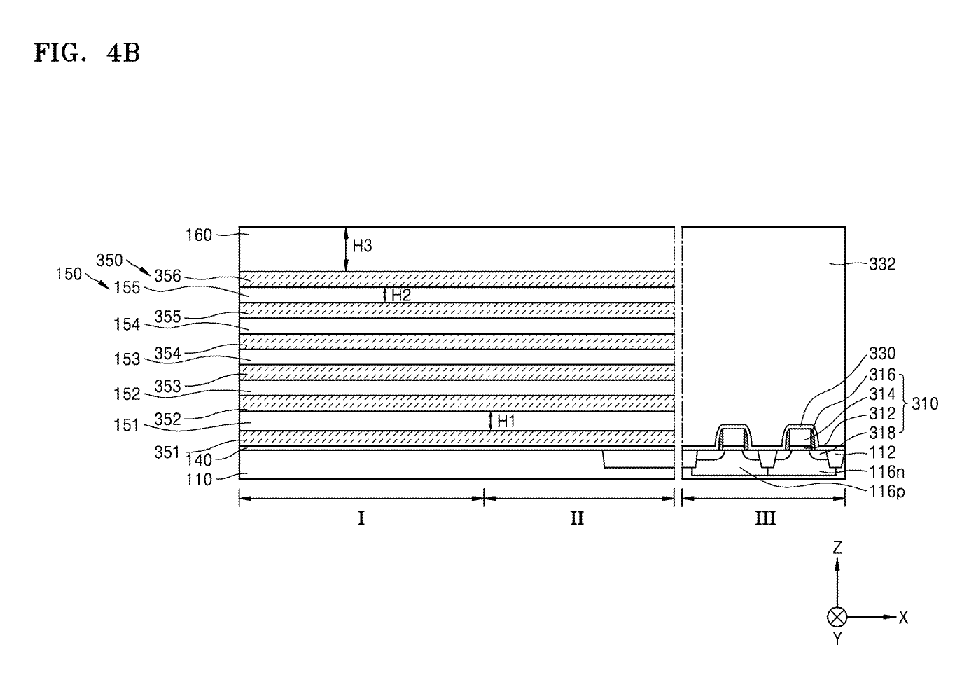

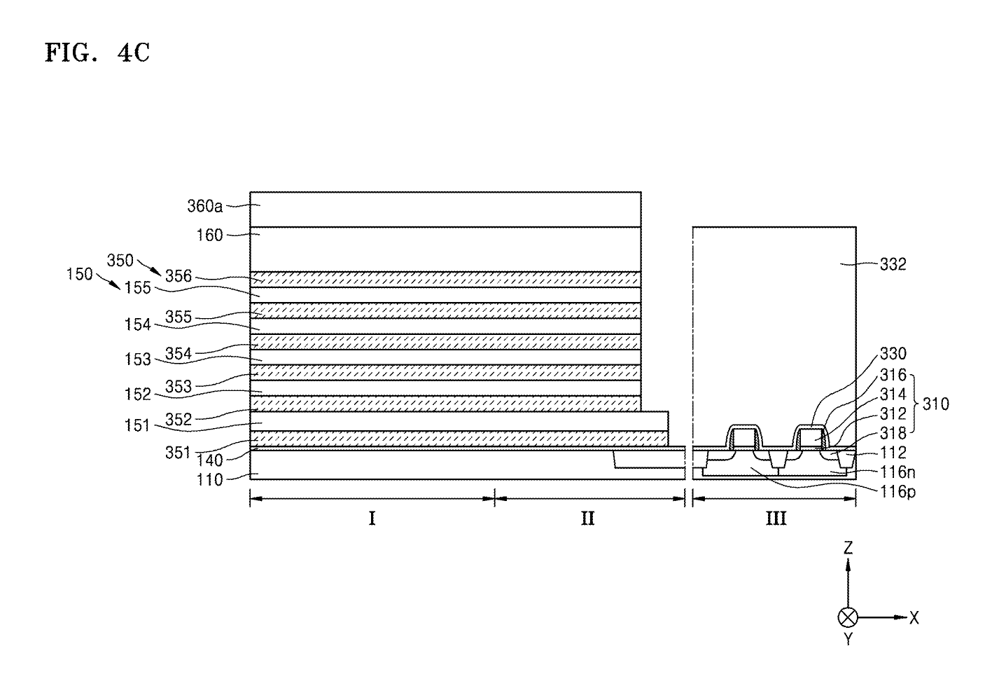

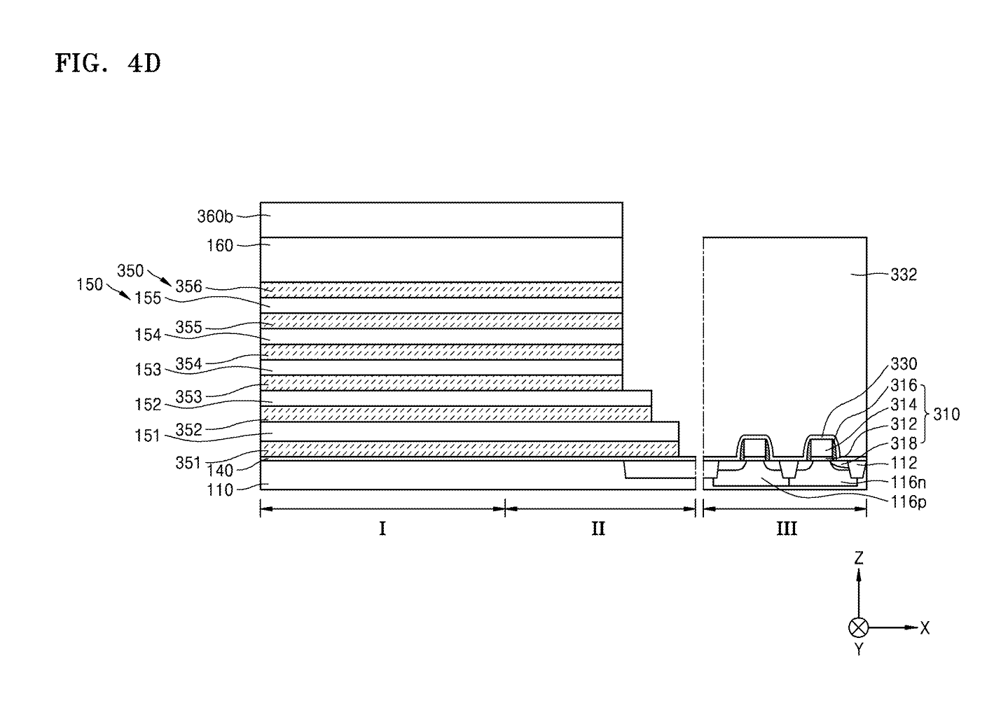

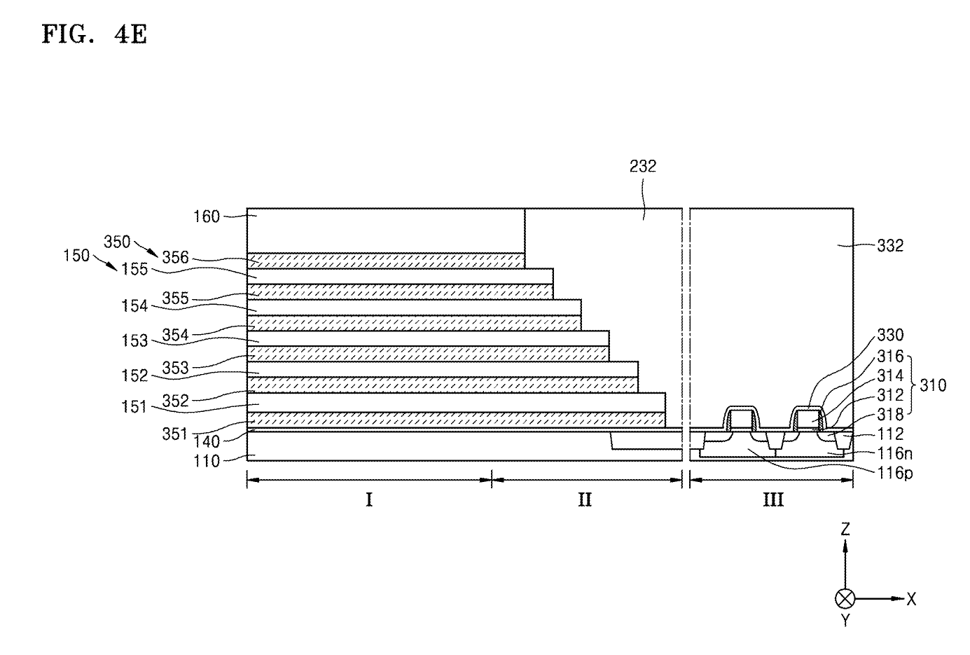

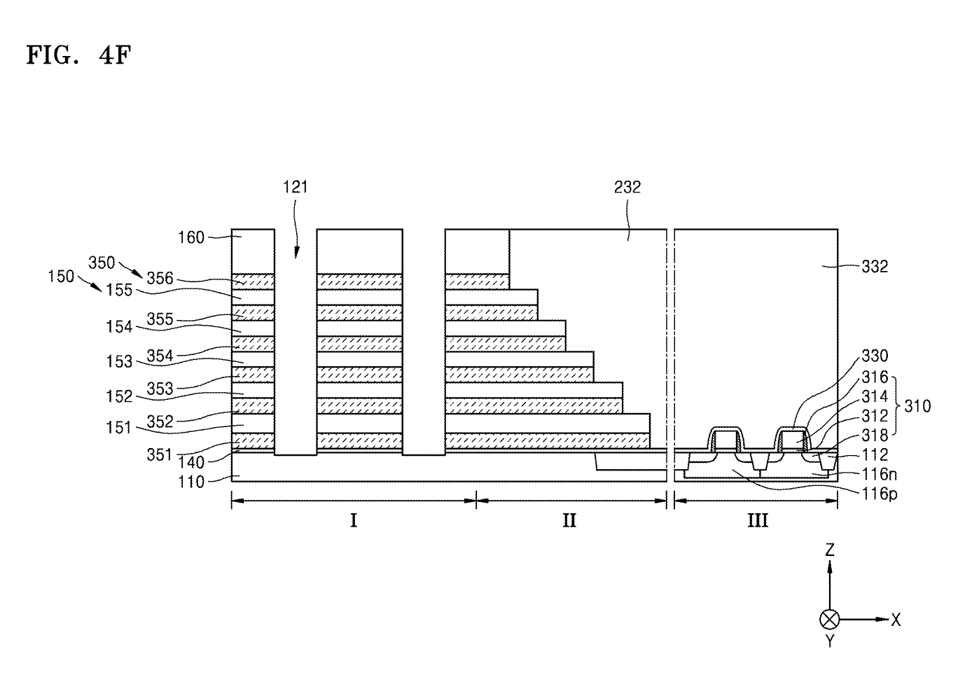

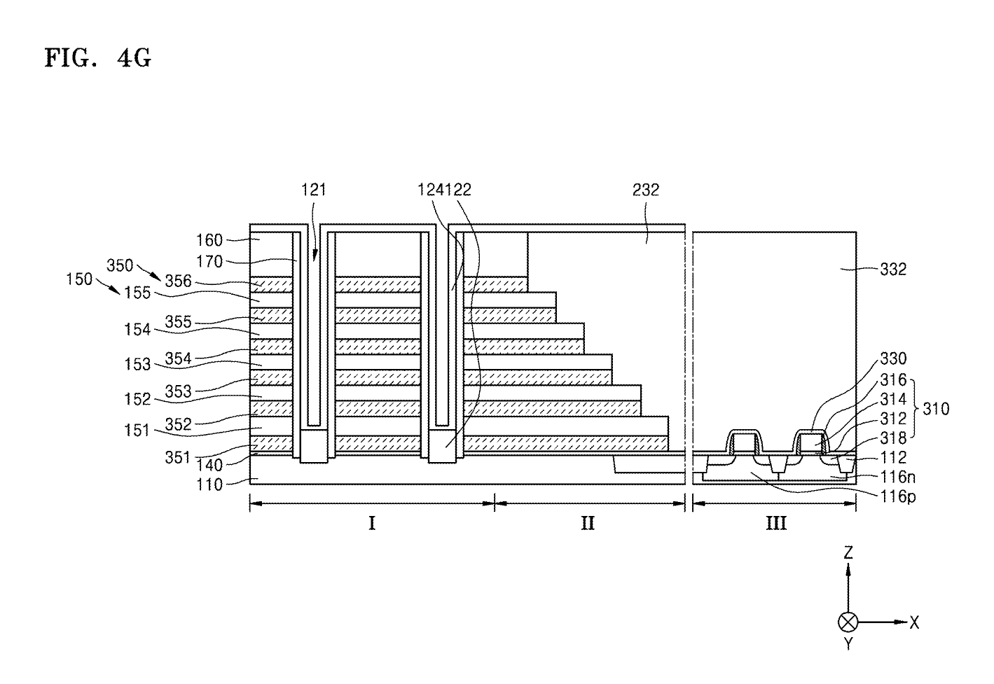

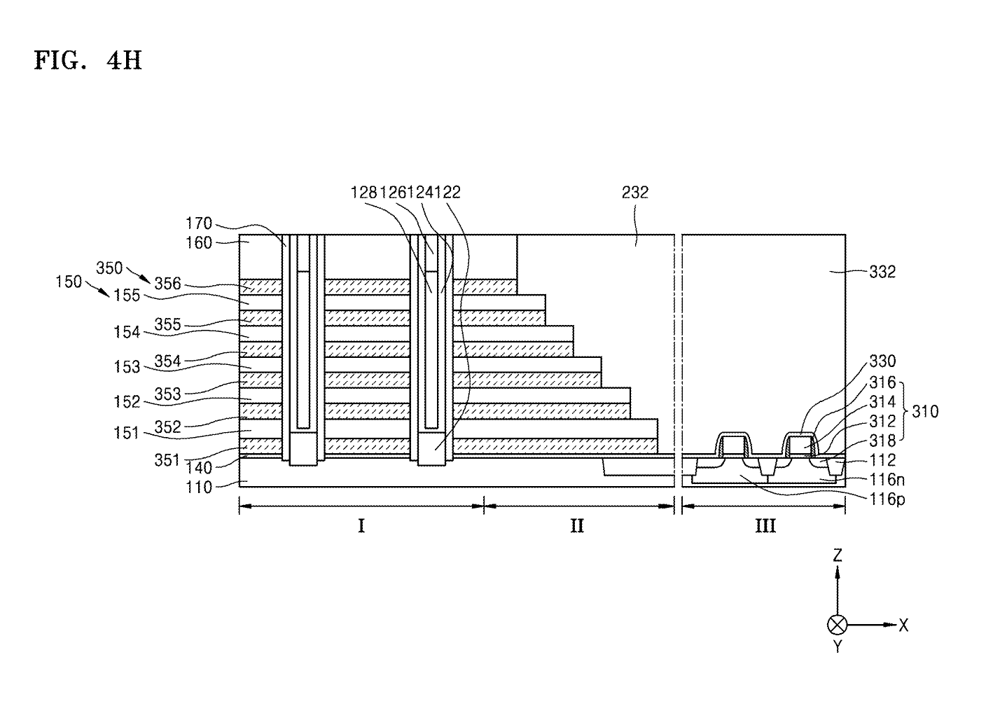

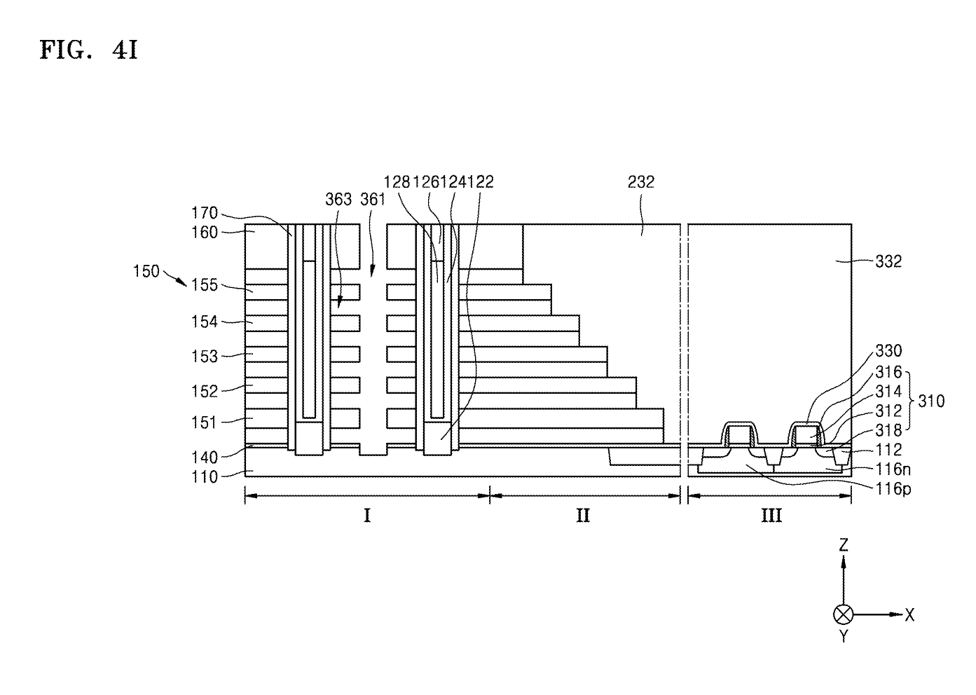

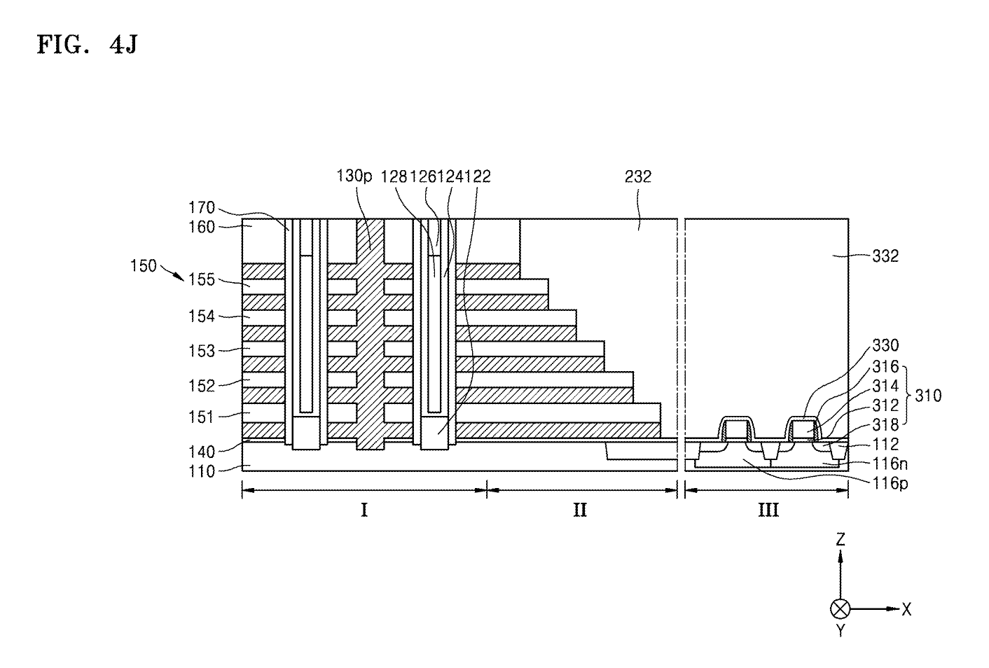

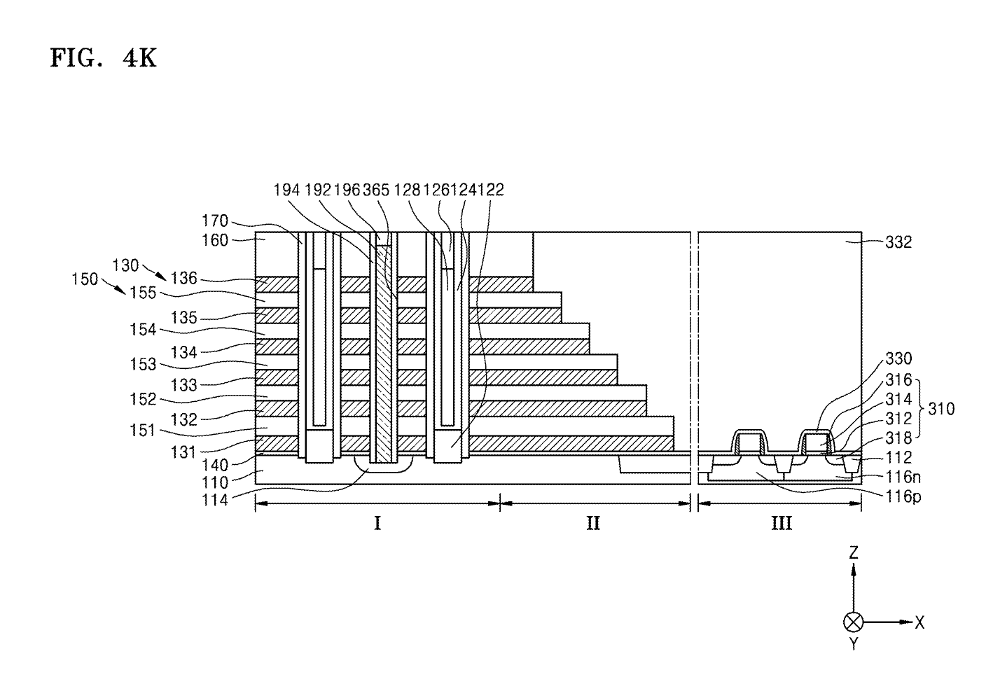

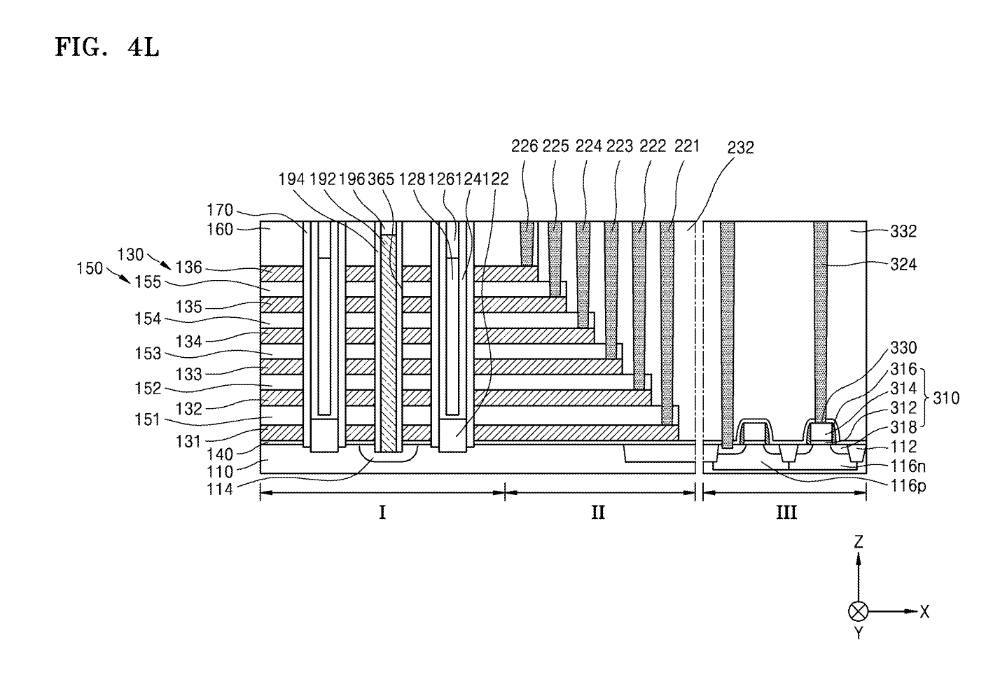

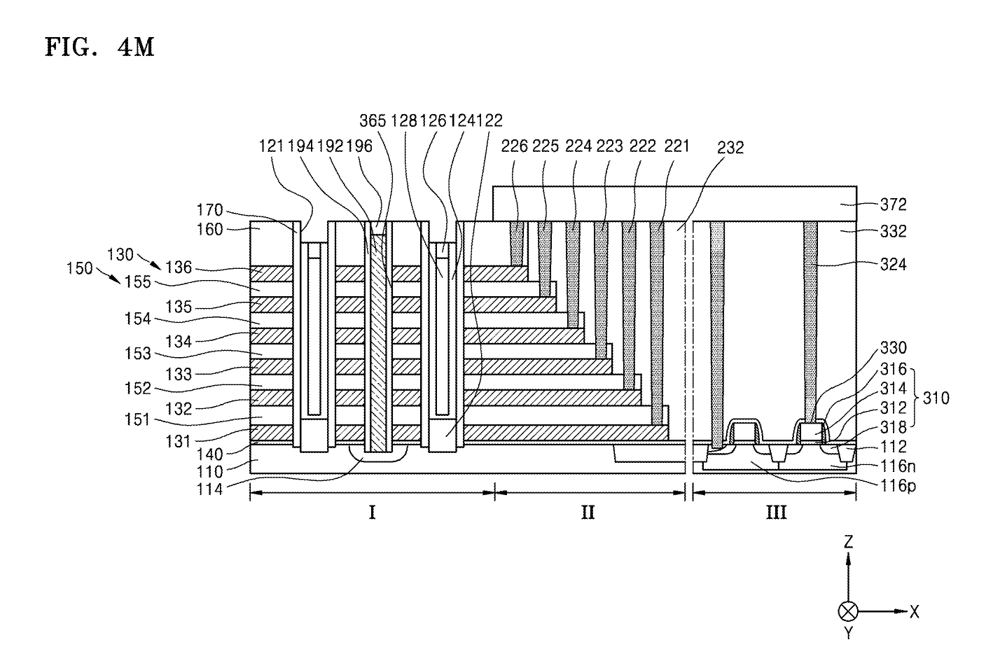

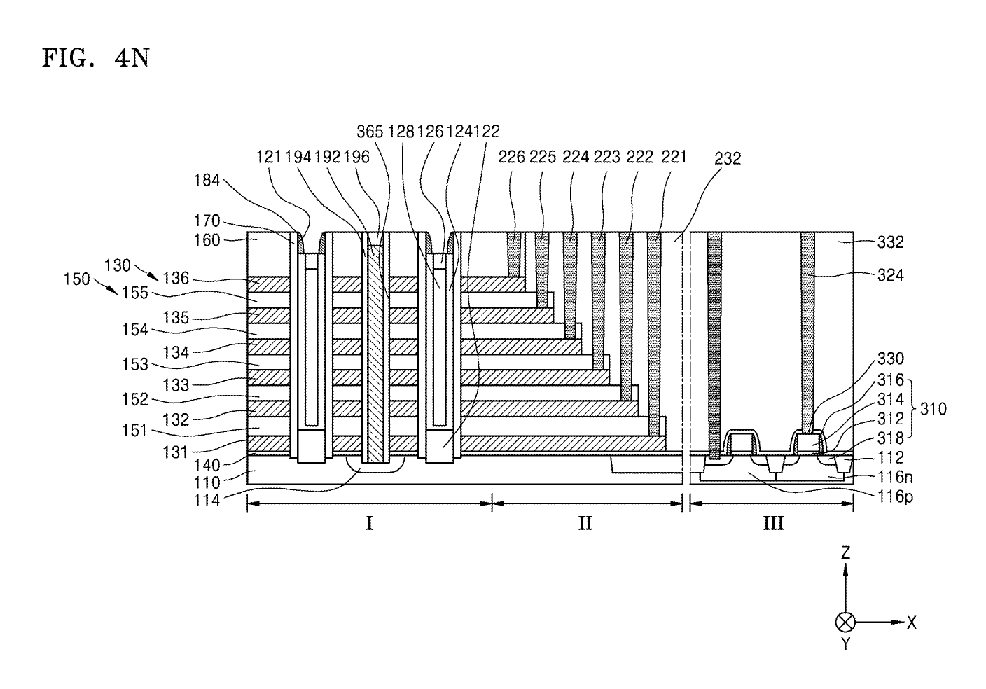

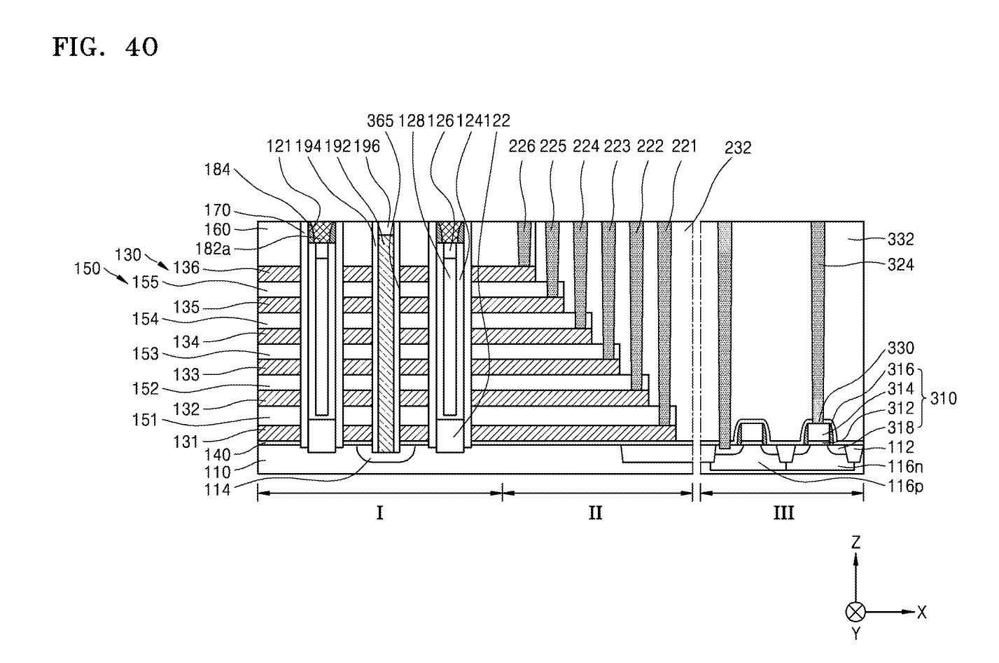

FIGS. 4A to 4O are cross-sectional views showing a fabricating method of a semiconductor device according to example embodiments. The fabricating method may be a method of forming the semiconductor device 1000a described by referring to FIGS. 3A and 3B.

Referring to FIG. 4A, after forming a buffer oxide layer (not shown) and a silicon nitride layer (not shown) on a substrate 110, the silicon nitride layer, the buffer oxide layer, and the substrate 110 may be sequentially patterned to form a buffer oxide layer pattern (not shown), a silicon nitride layer pattern (not shown), and a trench (not shown). An isolation region 112 may be formed by filling the trench with an insulating material such as silicon oxide. The isolation region 112 may be planarized until an upper surface of the silicon nitride layer pattern is exposed, and then the silicon nitride layer pattern and the buffer oxide layer pattern may be removed.

A sacrificial oxide layer (not shown) may be formed on the substrate 110, and then a p well 116p may be formed on a peripheral circuit region III of the substrate 110 by performing a first ion injection process with a first photoresist pattern (not shown). In addition, an n well 116n may be formed on the peripheral circuit region III of the substrate 110 by performing a second ion injection process with a second photoresist pattern (not shown). The p well 116p may be a region on which an NMOS transistor is formed, and the n well 116n may be a region on which a PMOS transistor is formed.

A peripheral gate insulating layer 312 may be formed on the substrate 110. The peripheral gate insulating layer 312 may be formed to include a first gate insulating layer (not shown) or a second gate insulating layer (not shown). Each of the first and second gate insulating layers may be a gate insulating layer for a low-voltage transistor or a gate insulating layer for a high-voltage transistor.

A peripheral gate conductive layer (not shown) may be formed on the peripheral gate insulating layer 312, and then the peripheral gate conductive layer may be patterned to form a peripheral gate electrode 314. The peripheral gate electrode 314 may be formed using a doped polysilicon. Alternatively, the peripheral gate electrode 314 may be formed in a multi-layered structure including a polysilicon layer and a metal layer, or including a polysilicon layer and a metal silicide layer.

A peripheral spacer 316 may be formed along a lateral wall of the peripheral gate electrode 314. For example, the peripheral spacer 316 may be formed by forming a silicon nitride layer on the peripheral gate electrode 314, and then performing an anisotropy etching process on the silicon nitride layer. Source/drain regions 318 may be formed at opposite sides of the peripheral gate electrode 314 on the substrate 110. For an NMOS transistor, the source/drain regions 318 may be doped with an n-type impurity, and for a PMOS transistor, the source/drain regions 318 may be doped with a p-type impurity. The source/drain regions 318 may have a lightly doped drain (LDD) structure.

In this manner, a peripheral gate structure 310 including the peripheral gate insulating layer 312, the peripheral gate electrode 314, the peripheral spacer 316, and the source/drain regions 318 may be fabricated.

An etch stop layer 330 may be formed on the peripheral gate structure 310. The etch stop layer 330 may be, for example, formed of an insulating material such as silicon nitride, silicon oxynitride, or silicon oxide. A third insulating interlayer 332 may be formed on the etch stop layer 330. The third insulating interlayer 332 may be, for example, formed of an insulating material such as silicon nitride, silicon oxynitride, or silicon oxide. After that, the third insulating interlayer 332 and the etch stop layer 330 on the peripheral circuit region III are allowed to remain whereas the third insulating interlayer 332 and the etch stop layer 330 on a cell region I and a connection region II are removed, thereby exposing the upper surface of the substrate 110 again.

Referring to FIG. 4B, a lower insulating layer 140 may be formed on the cell region I of the substrate 110. The lower insulating layer 140 may be formed of silicon oxide, silicon nitride, or silicon oxynitride using a chemical vapor deposition (CVD) process, an atomic layer deposition (ALD) process, or the like.

First to sixth sacrificial layers 351, 352, . . . , and 356 (collectively 350) and first to fifth insulating layers 151, 152, . . . , and 155 (collectively 150) may be alternately formed on the lower insulating layer 140. For example, the first sacrificial layer 351 is formed on the lower insulating layer 140, and the first insulating layer 151 is formed on the first sacrificial layer 351. In this manner, the sacrificial layers 350 and the insulating layers 150 may form a multi-layered structure. In example embodiments, the insulating layers 150 may be formed of silicon oxide, silicon nitride, silicon oxynitride, or the like using a CVD process or an ALD process. In example embodiments, the sacrificial layers 350 may be formed of a material having an etching selectivity with respect to the insulating layers 150. For example, the sacrificial layers 350 may be formed of polysilicon, silicon nitride, silicon carbide, or the like using a CVD process or an ALD process.

An upper insulating layer 160 may be formed on the sixth sacrificial layer 356 using silicon oxide, silicon nitride, or silicon oxynitride by a CVD process, an ALD process, or the like.

A first height H1 of the first insulating layer 151 may be formed to be greater than a height of each of the second to fifth insulating layers 152, 153, 154, and 155. For example, the first height H1 of the first insulating layer 151 may be formed to be greater that a second height H2 of the fifth insulating layer 155. In addition, a third height H3 of the upper insulating layer 160 may be greater than a height of each of the insulating layers 151, 152, . . . , and 155 (collectively 150). For example, the height H3 of the upper insulating layer 160 may be greater than a height of the uppermost insulating layer, that is, the second height H2 of the fifth insulating layer 155.

Referring to FIG. 4C, a first mask layer 360a may be formed on the upper insulating layer 160. The first mask layer 360a may be an etching mask used to remove the insulating layers 150 and the sacrificial layers 350 extended from the cell region I from the connection region II. Some portions of the upper insulating layer 160, the insulating layers 150 and the sacrificial layers 350, on which the first mask layer 360a is not formed, may be removed by sequentially etching until the upper surface of the first insulating layer 151 is exposed. The removing process may be an anisotropy etching process using dry etching or wet etching. For the dry etching, the removing process may be performed in a series of steps to sequentially etch the upper insulating layer 160, the insulating layers 150, and the sacrificial layers 350.

Referring to FIG. 4D, the first mask layer 360a (see FIG. 4C) may be removed, and then the upper surface of the upper insulating layer 160 may be exposed again.

Next, a second mask layer 360b may be formed to expose a desired (and/or predetermined) width from an edge portion of the upper insulating layer 160 on the connection region II. After that, some portions of the upper insulating layer 160, the insulating layers 150, and the sacrificial layers 350, on which the second mask layer 360b is not formed, may be removed by sequentially etching until the upper surface of the second insulating layer 152 is exposed.

The second mask layer 360b may be formed after removing the first mask layer 360a as described above. However, in example embodiments, the second mask layer 360b having less width and thickness than the first mask layer 360a may also be formed by performing a trimming process on the first mask layer 360a.

By repeatedly performing the removing processes of the insulating layers 150 and the sacrificial layers 350 as described above in connection with FIGS. 4C and 4D, the insulating layers 150 and the sacrificial layers 350 having stepped portions as illustrated in FIG. 4E may be formed.

Then, a first insulating interlayer 232 may be formed to cover the insulating layers 150, the sacrificial layers 350 and the upper insulating layer 160. The first insulating interlayer 232 may be formed of silicon oxide, silicon nitride, silicon oxynitride, or the like.

Next, a planarization process may be performed on the upper portions of the first insulating interlayer 232 and the third insulating interlayer 332 until the upper surface of the upper insulating layer 160 is exposed, and thus, the upper surfaces of the upper insulating layer 160, the first insulating interlayer 232, and the third insulating interlayer 332 may be positioned to be at substantially the same level.

Referring to FIG. 4F, a channel hole 121 penetrating the stacked structure of the insulating layers 150 and the sacrificial layers 350 may be formed. For example, the channel hole 121 may penetrate through the lower insulating layer 140 to expose the upper surface of the substrate 110. In the process of forming the channel hole 121, the upper surface of the substrate 110 may be exposed on the bottom portion of the channel hole 121, and then excessively etched to be recessed to a desired (and/or predetermined) depth.

The channel hole 121 may extend in the Z direction, which is perpendicular to the main surface of the substrate 110, and be spaced apart from one another by a desired (and/or predetermined) distance in the X direction and in the Y direction. The horizontal cross-sectional area of the channel hole 121 may have a circular shape, but is not limited thereto. The horizontal cross-sectional area of the channel hole 121 may have various shapes.

Referring to FIG. 4G, an insulating layer (not shown) is formed on the inner wall of the channel hole 121 and the upper insulating layer 160, and then an anisotropy etching process is performed on the insulating layer to form a gate insulating layer 170 covering the lateral wall of the channel hole 121.

In this case, a bottom surface of the gate insulating layer 170 may contact the upper surface of the substrate 110 exposed via the channel hole 121, and the lateral wall of the gate insulating layer 170 may be formed to cover substantially the entire lateral wall of the channel hole 121. By removing the insulating layer formed on the upper portion of the upper insulating layer 160 through the anisotropy etching process, the upper surface of the upper insulating layer 160 may be exposed again.

Then, a first channel layer 122 may be formed at the bottom portion of the channel hole 121. In example embodiments, the first channel layer 122 may be grown from the substrate 110, which is exposed at the bottom portion of the channel hole 121, by performing a selective epitaxial growth (SEG) process. As illustrated in FIG. 4G, the first channel layer 122 may be grown until the upper surface of the first channel layer 122 may be formed to be higher than that of the first sacrificial layer 351.

After that, p-type impurities such as aluminum (Al), boron (B), indium (In), or potassium (K) may be implanted into the first channel layer 122 through an ion injection process. In example embodiments, p-type impurities may be in-situ doped during the SEG process of growing the first channel layer 122.

A second channel layer 124 may be formed on the gate insulating layer 170, the first channel layer 122, which are inside the channel hole 121, and the upper insulating layer 160. The second channel layer 124 may be conformally formed with a desired (and/or predetermined) thickness on the inner wall of the channel hole 121. Therefore, the inside of the channel hole 121 may not be filled fully, and the upper surface of the first channel layer 122 may be covered by the second channel layer 124 so as not to be exposed inside the channel hole 121.

In example embodiments, the second channel layer 124 may be formed of polysilicon by performing an ALD process, a CVD process, and the like. Selectively, in a forming process of the second channel layer 124, n-type impurities such as phosphorous (P), arsenic (As), or antimony (Sb), and p-type impurities such as aluminum (Al), boron (B), indium (In), or potassium (K) may be in-situ doped.

Referring to FIG. 4H, after forming an insulating layer (not shown) on the second channel layer 124 to fill the channel hole 121 (see FIG. 4F), a planarization process is performed on the upper portions of the insulating layer and the second channel layer 124 to form a buried insulating layer 128, which fill the inside of the channel hole 121, until the upper surface of the upper insulating layer 160 is exposed. By performing the planarization process, some portions of the second channel layer 124 that are positioned on the upper insulating layer 160 are removed, thereby only leaving the other portions of the second channel layer 124 that are positioned inside of the channel hole 121.

Then, an etch-back process may be performed on the upper portion of the buried insulating layer 128 until the upper surface of the buried insulating layer 128 is lower than the upper surface of the upper insulating layer 160, thereby re-opening the channel hole 121.

A conductive layer (not shown) may be formed on the buried insulating layer 128 and the second channel layer 124 inside the channel hole 121, and then a planarization process may be performed on the upper portion of the conductive layer until the upper surface of the insulating layer 160 is exposed, thereby forming a third channel layer 126 that fills the channel hole 121. Here, an upper surface of the third channel layer 126 and the upper surface of the upper insulating layer 160 may be formed to be at substantially the same level.

Selectively, n-type impurities such as phosphorous (P), arsenic (As), or antimony (Sb) may be implanted into the third channel layer 126 through an ion injection process. In example embodiments, n-type impurities such as phosphorous (P), arsenic (As), or antimony (Sb) may be in-situ doped in the process of forming the third channel layer 126.

Referring to FIG. 4I, a first opening 361 may be formed to penetrate a stacked structure of the insulating layers 150 and the sacrificial layers 350 and to extend in the Y direction. Some portions of the lower insulating layer 140, which are formed at a bottom portion of the first opening 361, may be removed to expose the upper surface of the substrate 100 via the first opening 361.

After that, the sacrificial layers 350 may be removed to form a second opening 363 between two adjacent insulating layers 150.

For example, the process of forming the second opening 363 may be a wet etching process with an etchant having an etching selectivity with respect to the sacrificial layers 350. For example, in a case in which the sacrificial layers 350 includes silicon nitride, the sacrificial layers 350 may be removed through a wet etching process using an etchant including a phosphoric acid (H3PO4).

In this case, the lateral walls of the gate insulating layer 170 may be exposed by the second opening 363.

Referring to FIG. 4J, a diffusion barrier layer 178 (see FIG. 2B) may be formed in a desired (and/or predetermined) thickness on the lateral walls of the first opening 361 (see FIG. 4I) and the second opening 363 (see FIG. 4I). Then, a preliminary gate conductive layer 130p may be formed to fill the first opening 361 and the second opening 363. Selectively, planarization process may be performed on an upper portion of the preliminary gate conductive layer 130p until the upper surface of the upper insulating layer 160 is exposed. The preliminary gate conductive layer 130p may include, for example, tungsten, cobalt, nickel, tantalum, tungsten nitride, tungsten silicide, cobalt silicide, nickel silicide, tantalum silicide, or the like. In example embodiments, the preliminary gate conductive layer 130p may be formed through an electroplating process, an electroless plating process, or the like.

Referring to FIG. 4K, a third opening 365 extending in the Y direction and exposing the surface of the substrate 110 may be formed. In the process of forming the third opening 365, gate electrodes 131, 132, . . . , and 136 (collectively 130) to fill the second opening 363 (see FIG. 4i) may be formed.

Here, some portions of the substrate 110 that are exposed at a bottom portion of the third opening 365 may be excessively etched, and then the upper surface of the substrate 110 may be recessed to a desired (and/or predetermined) depth.

Then, an impurity may be implanted into the exposed portion of the substrate 110 to form a common source region 114.

After that, an insulating layer (not shown) may be formed on the inner wall of the upper insulating layer 160 and the third opening 365, and thus an anisotropy etching process may be performed on the insulating layer to form a common source line spacer 194 on the lateral wall of the third opening 365. The common source line spacer 194 may be, for example, formed of silicon nitride, silicon oxynitride, silicon oxide, or the like.

Next, after filling the third opening 365 with a second conductive layer (not shown), the upper portion of the second conductive layer may be planarized until the upper surface of the upper insulating layer 160 is exposed, and an etch-back process may be performed on the upper portion of the second conductive layer so that a common source line 192 is formed to fill the third opening 365 from the bottom portion thereof to a desired (and/or predetermined) height. For example, the common source line 192 may be formed of tungsten, tantalum, cobalt, tungsten silicide, tantalum silicide, cobalt silicide, or the like. The common source line 192 may be connected to the common source region 114.

After forming an insulating layer (not shown) on the upper insulating layer 160, the lateral wall of the third opening 365, and the common source line 192, a planarization process may be performed on the upper portion of the insulating layer until the upper surface of the upper insulating layer 160 is exposed so that a common source line insulating layer 196 filling the third opening 365 may be formed on the common source line 192. The common source line insulating layer 196 may be, for example, formed of silicon nitride, silicon oxynitride, silicon oxide, or the like.

Referring to FIG. 4L, first to sixth contact holes (not shown) that expose the upper surfaces of the first to sixth gate electrodes 132, 132, 133, 134, 135, and 136 may be formed in the first insulating interlayer 232. Each of the first to sixth gate electrodes 131, 132, 133, 134, 135, and 136 has a different depth from the upper surface of the first insulating interlayer 232, and thus may be sequentially patterned to from the first to sixth contact holes.

Then, a conductive layer (not shown) may be formed on the first insulating interlayer 232, and a planarization process may be performed on the upper portion of the conductive layer to form first to sixth contact plugs 221, 222, 223, 224, 225, and 226 filling the inside of the first to sixth contact holes.

In example embodiments, a peripheral contact hole (not shown) exposing the peripheral gate structure 310 may be formed in the third insulating interlayer 332, and then a conductive layer (not shown) may be formed on the third insulating interlayer 332. After than a planarization process is performed on the upper portion of the conductive layer to form a peripheral contact plug 324 filling the inside of the peripheral contact hole.

Referring to FIG. 4M, a first protective layer 372 may be formed on the first insulating interlayer 232 and the third insulating interlayer 332 of the connection region II and the peripheral circuit region III. The first protective layer 372 may cover upper surfaces of the first to sixth contact plugs 221, 222, 223, 224, 225, and 226 and an upper surface of the peripheral contact plug 324.

Then, an etch-back process may be performed on the upper portions of the second and third channel layers 124 and 126, thereby re-opening the channel hole 121. In this regard, the upper surfaces of the second and third channel layers 124 and 126 may be positioned to be lower than the upper surface of the upper insulating layer 160.

Referring to FIG. 4N, the first protective layer 372 (see FIG. 4M) may be removed.

After forming an insulating layer (not shown) on the upper insulating layer 160 and the inner wall of the channel hole 121, an anisotropy etching process may be performed on the insulating layer to form a self-aligned contact spacer 184 on the lateral wall of the channel hole 121. In example embodiments, the self-aligned contact spacer 184 may be formed of silicon oxide, silicon oxynitride, silicon nitride, or the like by performing an ALD process, CVD process, or the like.

At least some portions of the upper surface of the third channel layer 126, which were covered by the insulating layer in the anisotropy etching process, may be exposed. In example embodiments, some portions of the upper surface of the second channel layer 124 may also be exposed depending on the thickness of the self-aligned contact spacer 184. For example, each of the self-aligned contact spacer 184 and the second channel layer 124 is aligned along the lateral wall of the channel hole 121, and thus in a case in which the maximum thickness of the self-aligned contact spacer 184 in the X direction is less than the thickness of the second channel layer 124 in the X direction, some portions of the upper surface of the second channel layer 124 may not be covered by the self-aligned contact spacer 184.

Then, the first protective layer 372 (see FIG. 4M) may be removed.

Referring to FIG. 4O, after forming a conductive layer (not shown), which fills the inner wall of the channel hole 121, on the upper insulating layer 160, a planarization process may be performed on the upper portion of the conductive layer until the upper surface of the upper insulating layer 160 is exposed so that a self-aligned contact 182a is formed on the inner wall of the channel hole 121. In example embodiments, the self-aligned contact 182a may be formed of tungsten, tantalum, cobalt, tungsten silicide, tantalum silicide, cobalt silicide, or the like.

The self-aligned contact 182a may be formed in which the bottom surface thereof contacts the upper surface of the third channel layer 126 and/or the upper surface of the second channel layer 124 using the self-aligned contact spacer 184 as an aligning spacer. The self-aligned contact 182a may be formed to fill the empty inside of the channel hole 121 defined by the self-aligned contact spacer 184, and thus an additional patterning process to form the self-aligned contact 182a may not be needed. Accordingly, a misalignment of contacts in the patterning process may be limited (and/or prevented). In example embodiments, the contact area between the self-aligned contact 182 and the third channel layer 126 and/or the second channel layer 124 may be increased, and thus the contact resistance between the channel layers 122, 124, and 126 and a bit line 186 (see FIG. 3A) that will be formed on the upper portion of the self-aligned contact 182a in the process described later.

In FIG. 4O, the process of forming the self-aligned contact 182a by using the self-aligned contact spacer 184 as an aligning spacer, but the self-aligned contact 182 (see FIG. 2A) may also be formed using the gate insulating layer 170 instead of the self-aligned contact spacer 184. In other words, by using some portions of gate insulating layer 170 on the lateral wall of the channel hole 121 as an aligning spacer, a conductive layer (not shown) filling the channel hole 121 may be formed on the upper insulating layer 160. Then a planarization process may be performed on the upper portion of the conductive layer to form the self-aligned contact 182. Even in this case, the semiconductor device 1000 described by referring to FIGS. 2A and 2B may be fabricated. The lateral wall of the self-aligned contact 182 contacts the lateral wall of the gate insulating layer 170, and the bottom surface of the self-aligned contact 182 contacts the entire upper surfaces of the second channel layer 124 and the third channel layer 126. Accordingly, the contact area between the bottom surface of the self-aligned contact 182 and the upper surfaces of the second and third channel layers 124 and 126 may be maximized, and thus the contact resistance between the bit line 186 (see FIG. 2A) and the channel layers 122, 124, and 126 may be reduced.

Then, referring to FIG. 3A again, a conductive layer (not shown) is formed on the upper insulating layer 160, the first insulating interlayer 232 and the third insulating interlayer 332, and then the conductive layer is patterned to form the bit line 186 on the upper insulating layer 160 and the self-aligned contact 182a; gate wiring lines 210 on the first insulating interlayer 232 and the contact plugs 220; and a peripheral wiring line 322 on the third insulating interlayer 332 and the peripheral contact plug 324.

After that, as illustrated in FIGS. 3A and 3B, a second insulating interlayer 234 may be formed to cover the bit line 186 and the gate wiring lines 210 on the upper insulating layer 160 and the first insulating interlayer 232. A fourth insulating interlayer 334 covering the peripheral wiring line 322 may be also be formed on the third insulating interlayer 332.

The semiconductor device 1000a is fabricated by performing the aforementioned processes.

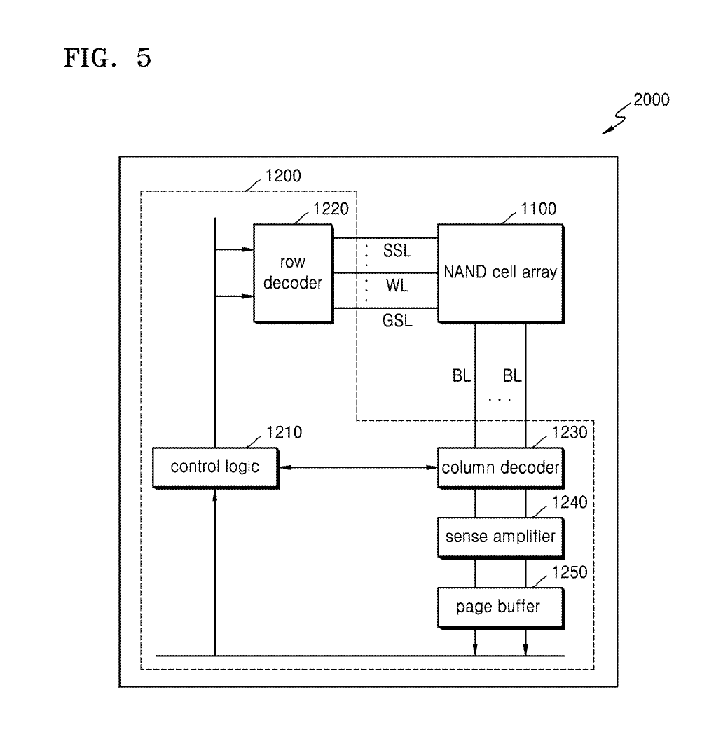

FIG. 5 is a schematic block diagram showing a nonvolatile memory device according to example embodiments.

Referring to FIG. 5, a NAND cell array 1100 may be connected to a core circuit unit 1200 in a nonvolatile memory device 2000. For example, the NAND cell array 1100 may include the semiconductor devices 1000 and 1000a having vertical structures as described by referring to FIGS. 2A to 3B. The core circuit unit 1200 may include a control logic 1210, a row decoder 1220, a column decoder 1230, a sense amplifier 1240, and a page buffer 1250.

The control logic 1210 may communicate with the row decoder 1220, the column decoder 1230, and the page buffer 1250. The row decoder 1220 may communicate with the NAND cell array 1100 via a plurality of string selection lines SSL, a plurality of word lines WL, and a plurality of ground selection lines GSL. The column decoder 1230 may communicate with the NAND cell array 1100 via a plurality of bit lines BL. The sense amplifier 1240 may be connected to the column decoder 1230 when the NAND cell array 1100 outputs a signal whereas the sense amplifier 1240 may not be connected to the column decoder 1230 when a signal is transmitted to the NAND cell array 1100.

For example, the control logic 1210 transmits a row address signal to the row decoder 1220, and the row decoder 1220 decodes the row address signal to transmit it to the NAND cell array 1100 via the string selection line SSL, the word line WL, and the ground selection line GSL. The control logic 1210 transmits a column address signal to the column decoder 1230 or the page buffer 1250, and the column decoder 1230 decodes the column address signal to transmit it to the NAND cell array 1100 via the bit lines BL. The signal of the NAND cell array 1100 may be transmitted to the sense amplifier 1240 via the column decoder 1230 to be amplified, and then be transmitted to the control logic 1210 via the page buffer 1250.

It should be understood that example embodiments described herein should be considered in a descriptive sense only and not for purposes of limitation. Descriptions of features or aspects within each device or method according to example embodiments should typically be considered as available for other similar features or aspects in other devices or methods according to example embodiments. While some example embodiments have been particularly shown and described, it will be understood by one of ordinary skill in the art that variations in form and detail may be made therein without departing from the spirit and scope of the claims.

What is claimed is:

1. A semiconductor device comprising:
a substrate;
a plurality of word lines spaced apart from each other in a first direction on the substrate, the first direction being perpendicular to an upper surface of the substrate, the plurality of word lines defining a channel hole that exposes the upper surface of the substrate;
a channel layer in the channel hole;
a gate insulating layer in the channel hole along an inner wall of the channel hole, the gate insulating layer being between the plurality of word lines and the channel layer; and
a self-aligned contact on an upper portion of the channel layer in the channel hole, the self-aligned contact including a width that increases from top to bottom.

2. The semiconductor device of claim 1, wherein the self-aligned contact and a portion of the gate insulating layer are at substantially the same level.

3. The semiconductor device of claim 1, wherein a bottom surface of the self-aligned contact contacts at least a portion of an upper surface of the channel layer.

4. The semiconductor device of claim 1, wherein an upper surface of the gate insulating layer is above an uppermost surface of the plurality of word lines.

5. The semiconductor device of claim 1, wherein a portion of the gate insulating layer surrounds a lateral wall of the self-aligned contact.

6. The semiconductor device of claim 1, further comprising:
a contact spacer between the self-aligned contact and the gate insulating layer.

7. The semiconductor device of claim 6, wherein the contact spacer contacts at least a portion of a lateral wall of the self-aligned contact.

8. The semiconductor device of claim 6, wherein the contact spacer surrounds a lateral wall of the self-aligned contact.

9. The semiconductor device of claim 1, further comprising:
an upper insulating layer on the plurality of word lines, wherein
the upper insulating layer further defines the channel hole above a portion of the channel hole defined by the plurality of word lines, and
a portion of the gate insulating layer and the upper insulating layer are at substantially the same level.

10. The semiconductor device of claim 9, wherein an upper surface of the self-aligned contact and an upper surface of the upper insulating layer are at substantially the same level.

11. A semiconductor device comprising:
a substrate;
a channel layer on the substrate, the channel layer extending in a first direction that is perpendicular to an upper surface of the substrate;
a plurality of word lines arranged along a lateral wall of the channel layer, the plurality of word lines being spaced apart from each other in the first direction;
a gate insulating layer between the channel layer and the plurality of word lines;
a bit line contact on the channel layer; and
a contact spacer surrounding a lateral wall of the bit line contact, the contact spacer being positioned at substantially the same level as at least a portion of the gate insulating layer.

12. The semiconductor device of claim 11, wherein
the gate insulating layer surrounds the channel layer and extends in the first direction, and
an upper surface of the gate insulating layer and an upper surface of the contact spacer are at substantially the same level.

13. The semiconductor device of claim 11, wherein the at least a portion of the gate insulating layer contacts the contact spacer.

14. The semiconductor device of claim 11, further comprising:
an upper insulating layer surrounding the at least a portion of the gate insulating layer, wherein
the at least a portion of the gate insulating layer is between the contact spacer and the upper insulating layer.

15. The semiconductor device of claim 11, wherein an upper surface of the contact spacer and an upper surface of the bit line contact are at substantially the same level.

16. A semiconductor device comprising:
a substrate;
a memory cell string on the substrate,
the memory cell string including a plurality of memory cells stacked on top of each other between a ground select transistor and a string select transistor;
a self-aligned contact, the self-aligned contact including a width that increases from top to bottom; and
a bit line connected to a top of the memory cell string through the self-aligned contact.

17. The semiconductor device of claim 16, wherein
the memory cell string includes a channel layer, a plurality of electrodes spaced apart from each other in a vertical direction along a sidewall of the channel layer, and a gate insulating layer between the channel layer and the plurality of electrodes,
the self-aligned contact is on top of the channel layer, and
the self-aligned contact is surrounded by the gate insulating layer.

18. The semiconductor device of claim 17, wherein the bit line contacts an upper surface of the self-aligned contact and an upper surface of the gate insulating layer.

19. The semiconductor device of claim 17, further comprising:
a self-aligned contact spacer between the gate insulating layer and the self-aligned contact, wherein
a width of the self-aligned contact spacer decreases from top to bottom.

20. A non-volatile memory device, comprising:
the semiconductor device of claim 17,
a plurality of memory cell strings arranged in rows and columns on the substrate, the plurality of memory cell strings including the memory cell string;
a plurality of bit lines, the plurality of bit lines including the bit line;
a plurality of bit line contacts, plurality bit line contacts including the bit line contact;
a plurality of word lines; and
a core circuit unit connected to the rows and columns of the plurality of memory cell strings through the plurality of word lines and the plurality of bit lines, respectively, wherein
each one of the plurality of memory cell strings is connected to a corresponding one of the bit lines through a corresponding one of the self-aligned contacts.
